(19) United States
(12) Patent Application Publication
(10) Pub. No.: US 2026/0096198 A1
(43) Pub. Date: Apr. 2, 2026

(54) PROTECTIVE STRUCTURES IN STACKING TRANSISTORS AND METHODS OF FORMING SAME

(71) Applicant: Taiwan Semiconductor Manufacturing Co., Ltd., Hsinchu (TW)

(72) Inventors: Kuan-Kan Hu, Hsinchu (TW); Che Chi Shih, Taoyuan (TW); Zhi-Chang Lin, Zhubei (TW); Tsung-Kai Chiu, Hsinchu (TW); Ku-Feng Yang, Baoshan Township (TW); Szuya Liao, Zhubei (TW)

(21) Appl. No.: 19/038,095

(22) Filed: Jan. 27, 2025

Related U.S. Application Data
(60) Provisional application No. 63/699,955, filed on Sep. 27, 2024.

(51) Int. Cl. H10D 84/85; H10D 84/01

(52) U.S. Cl. CPC H10D 84/854; H10D 84/0167; H10D 84/017; H10D 84/0186; H10D 84/0188; H10D 84/851

(57) ABSTRACT

A semiconductor device comprising includes a plurality of first nanostructures extending between first source/drain regions and a plurality of second nanostructures overlapping the plurality of first nanostructures, the plurality of second nanostructure extending between second source/drain regions. The device further includes a first insulating protective layer overlapping the second nanostructures; a first gate stack around the plurality of first nanostructures; and a second gate stack over the first gate stack and disposed around the plurality of second nanostructures. A lateral surface of the first insulating protective layer is level with a top surface of the first gate stack.

### PRIORITY CLAIM AND CROSS-REFERENCE

This application claims the benefit of the following provisionally filed U.S. Patent application: Application No. 63/699,955, filed on Sep. 27, 2024, which application is hereby incorporated herein by reference.

### BACKGROUND

Semiconductor devices are used in a variety of electronic applications such as personal computers, cell phones, digital cameras, and other electronic equipment. Semiconductor devices are typically fabricated by sequentially depositing insulating or dielectric layers, conductive layers, and semiconductor layers over a semiconductor substrate, and patterning the various material layers using lithography to form circuit components and elements thereon.

The semiconductor industry continues to improve the integration density of various electronic components (e.g., transistors, diodes, resistors, capacitors, etc.) by continual reductions in minimum feature size, which allow more components to be integrated into a given area. As the semiconductor industry further progresses towards increased device density, higher performance, and lower costs, challenges from both fabrication and design have led to stacked device configurations, such as stacking transistors, which include complementary field effect transistors (CFETs). As the minimum feature sizes are reduced, however, additional features are introduced.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates a perspective view of example stacking transistors in accordance with some embodiments.

FIGS. 2A, 2B, 3, 4, 5, 6, 7, 8A, 8B, 9A, 9B, 10A, 10B, 11, and 12 are views of intermediate stages in the manufacturing of a stacking transistor in accordance with some embodiments.

FIGS. 13A, 13B, 14, 15A, 15B, and 16 are views of intermediate stages in the manufacturing of a stacking transistor in accordance with some embodiments.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “underlying,” “below,” “lower,” “overlying,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

A stacking transistor, such as a CFET, and the method of forming the same are provided. The stacking transistor includes two vertically stacked transistors with vertically stacked channel regions (e.g., stacked nanostructures, fins, or the like). In various embodiments, insulating protection layers are formed over and under the vertically stacked channel regions. For example, an upper protection layer may be formed on a top surface of a topmost nanostructure of the vertically stacked channel regions, and/or a lower protection layer may be formed on a bottom surface of a bottommost nanostructure of the vertically stacked channel regions. The lower protection layer may provide a stop layer that facilitates the formation of a backside gate contact with fewer manufacturing errors. The upper protection layer may provide a stop layer for planarizing an upper gate stack of the upper transistor. In this manner, a gate height of the upper gate stack can be reduced, reducing device capacitance and improving performance.

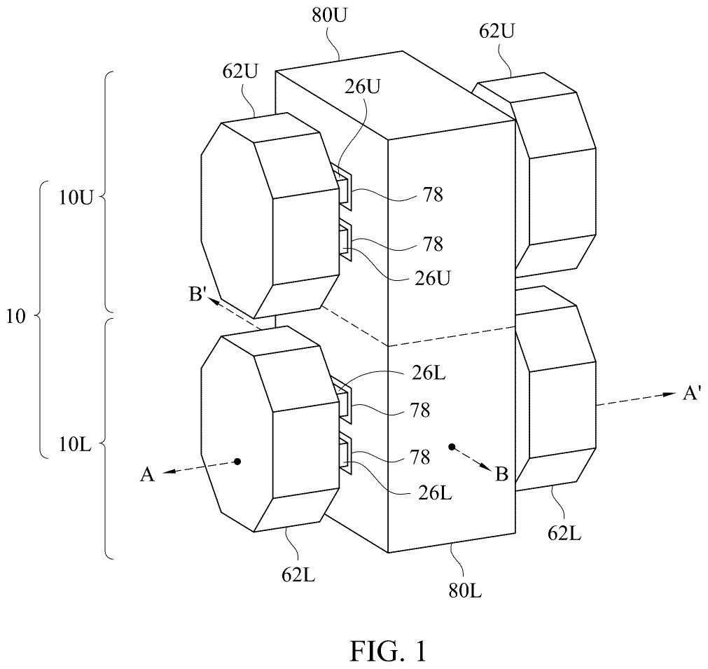

FIG. 1 illustrates a simplified example of a stacking transistor 10 (including FETs (transistors) 10U and 10L) in accordance with some embodiments. FIG. 1 is a three-dimensional view, and some features of the stacking transistor are omitted for illustration clarity.

The stacking transistor includes multiple vertically stacked FETs. For example, a stacking transistor may include a lower nanostructure-FET 10L of a first device type (e.g., n-type/p-type) and an upper nanostructure-FET 10U of a second device type (e.g., p-type/n-type). When the stacking transistor is a CFET, the second device type of the upper nanostructure-FET 10U is opposite to the first device type of the lower nanostructure-FET 10L. The nanostructure-FETs 10U and 10L include semiconductor nanostructures 26 (including lower semiconductor nanostructures 26L and upper semiconductor nanostructures 26U), where the semiconductor nanostructures 26 act as the channel regions for the nanostructure-FETs. The lower semiconductor nanostructures 26L are for the lower nanostructure-FET 10L, and the upper semiconductor nanostructures 26U are for the upper nanostructure-FET 10U. In other embodiments, the stacking transistors may be applied to other types of transistors (e.g., finFETs, or the like) as well.

Gate dielectrics 78 encircle the respective semiconductor nanostructures 26. Gate electrodes 80 (including a lower gate electrode 80L and an upper gate electrode 80U) are over the gate dielectrics 78. Source/drain regions 62 (including lower source/drain regions 62L and upper source/drain regions 62U) are disposed on opposing sides of the gate dielectrics 78 and the respective gate electrodes 80. Each of the source/drain regions 62 may refer to a source or a drain, individually or collectively dependent upon the context. Isolation features (not shown) may be formed to separate desired ones of the source/drain regions 62 and/or desired ones of the gate electrodes 80.

FIG. 1 further illustrates reference cross-sections that are used in later figures. Cross-section A-A′ is a vertical cross-section that is parallel to a longitudinal axis of the semiconductor nanostructures 26 of the stacking transistor 10 and in a direction of, for example, a current flow between the source/drain regions 62 of the stacking transistor 10. Cross-section B-B′ is a vertical cross-section that is perpendicular to cross-section A-A′ and along a longitudinal axis of a gate electrodes 80 of the stacking transistor 10.

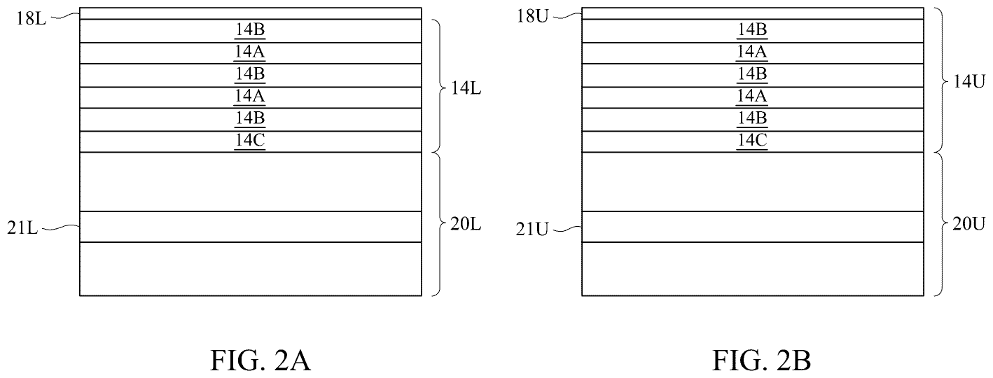

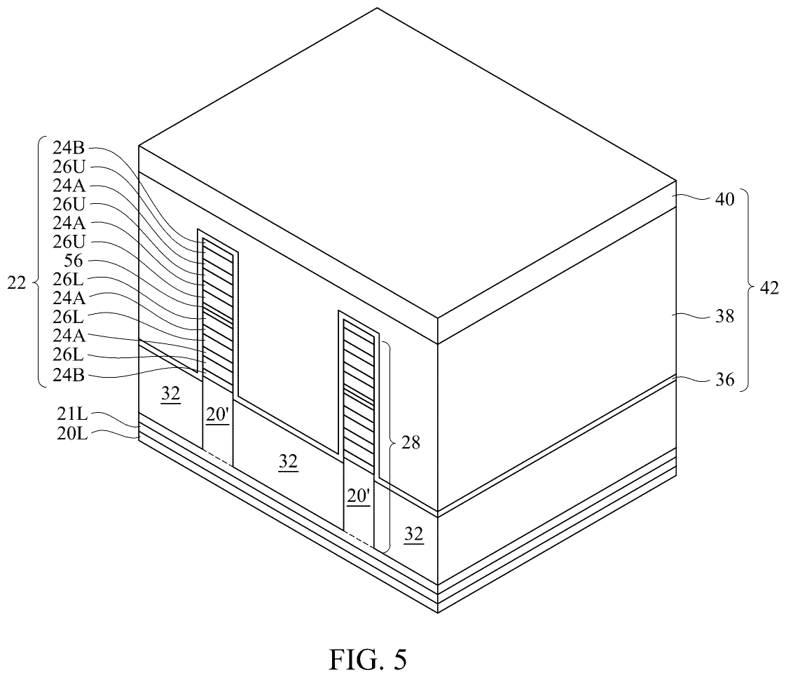

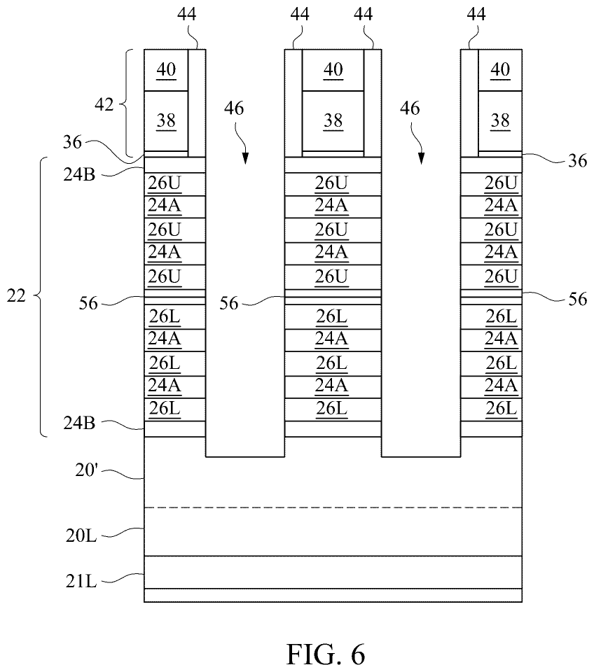

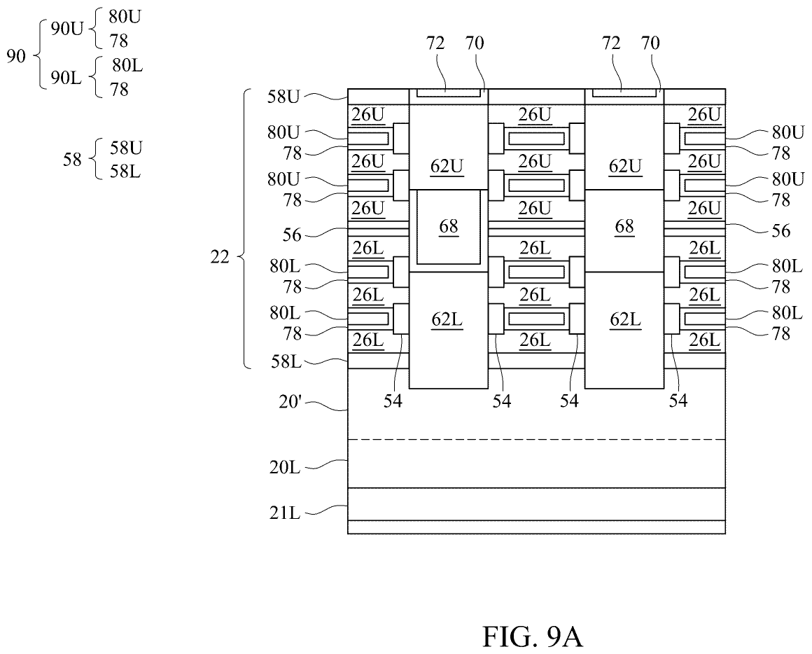

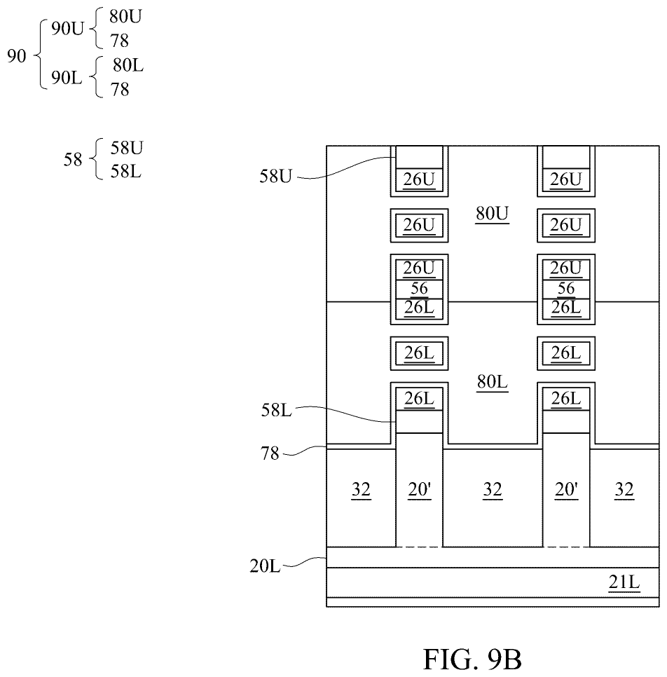

FIGS. 2A through 12 illustrate the cross-sectional views of intermediate stages in the formation of stacking transistors (as schematically represented in FIG. 1) in accordance with some embodiments. FIGS. 2A, 2B, 3, and 4 illustrate general cross-sectional views. FIG. 5 illustrates a perspective view similar to FIG. 1. FIGS. 6, 7, 8A, 8B, 9A, and 10A illustrate cross-sectional views along a similar cross-section as reference cross-section A-A′ in FIG. 1. FIGS. 9B, 10B, 11, and 12 illustrate cross-sectional views along a similar cross-section as reference cross-section B-B′ in FIG. 1.

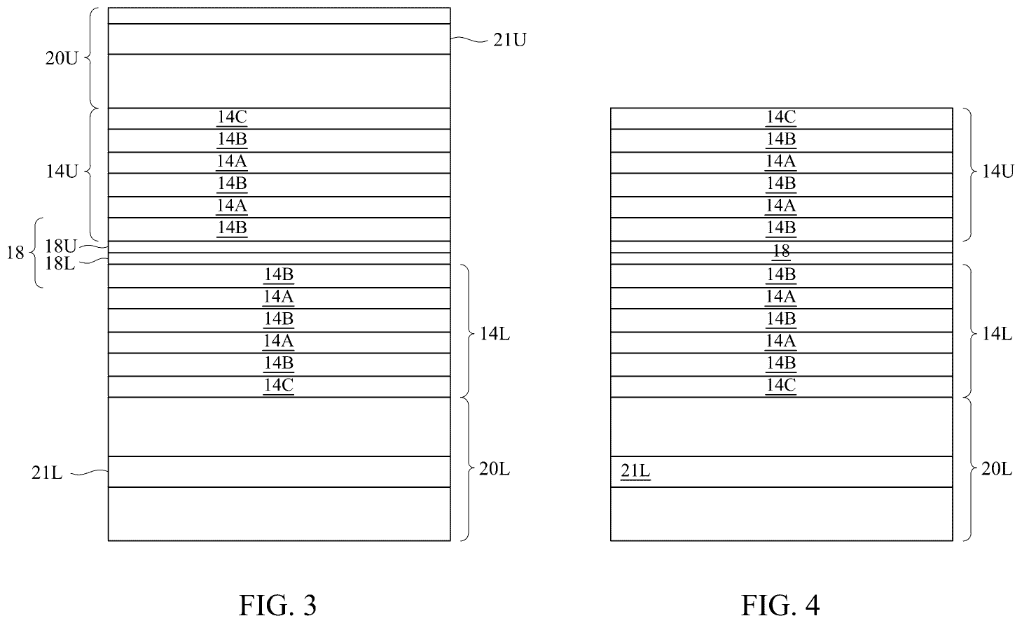

In FIGS. 2A and 2B, two substrates 20L and 20U are separately provided. FIG. 2A illustrates a substrate 20L, and FIG. 2B illustrates a substrate 20U. In subsequently processes, the substrate 20U may be bonded over the substrate 20L (see FIG. 3). As such, the substrate 20L may be referred to as a lower substrate 20L, and the substrate 20U may also be referred to as an upper substrate 20U. Each of the substrates 20L and 20U may be a semiconductor substrate, such as a bulk semiconductor, a semiconductor-on-insulator (SOI) substrate, or the like, which may be doped (e.g., with a p-type or an n-type dopant) or undoped. The substrates 20L and 20U may each be a wafer, such as a silicon wafer. Generally, an SOI substrate is a layer of a semiconductor material formed on an insulator layer. The insulator layer may be, for example, a buried oxide (BOX) layer, a silicon oxide layer, or the like. The insulator layer is provided on a substrate, typically a silicon or glass substrate. Other substrates, such as a multi-layered or gradient substrate may also be used. In some embodiments, the semiconductor material of the substrates 20L and 20U may include silicon; germanium; a compound semiconductor including carbon-doped silicon, gallium arsenide, gallium phosphide, indium phosphide, indium arsenide, and/or indium antimonide; an alloy semiconductor including silicon-germanium, gallium arsenide phosphide, aluminum indium arsenide, aluminum gallium arsenide, gallium indium arsenide, gallium indium phosphide, and/or gallium indium arsenide phosphide; or combinations thereof.

A multi-layer stack 14L and the multi-layer stack 14U are formed over each of the lower substrate 20L and the upper substrate 20U, respectively. Each of the multi-layer stacks 14U and 14L includes alternating dummy semiconductor layers 14A and semiconductor layers 14B, which are collectively disposed over a dummy semiconductor layer 14C. As subsequently described in greater detail, the dummy semiconductor layers 14A and 14C will be removed, and the semiconductor layers 14B will be patterned to form channel regions of a stacking transistor. For example, the semiconductor layers 14B on the substrate 20L may be patterned to form channel regions of a lower transistor, and the semiconductor layers 14B on the substrate 20U may be patterned to form channel regions of an upper transistor.

The dummy semiconductor layers 14A and 14C are formed of a first semiconductor material selected from the candidate semiconductor materials of the substrates 20L and 20U. The semiconductor layers 14B are formed of one or more second semiconductor material(s) also selected from the candidate semiconductor materials of the substrates 20L and 20U. Each layer of the multi-layer stack 14 may be grown by a process such as vapor phase epitaxy (VPE) or molecular beam epitaxy (MBE), deposited by a process such as chemical vapor deposition (CVD) or atomic layer deposition (ALD), or the like.

The semiconductor layers 14B on the substrate 20L may be formed of the same semiconductor material or may be formed of different semiconductor materials as the semiconductor layers 14B on the substrate 20U. In some embodiments, each of the semiconductor layers 14B is formed of a semiconductor material suitable for p-type devices and n-type devices, such as silicon. In some embodiments, the semiconductor layers 14B on the substrate 20U are formed of a semiconductor material suitable for p-type devices, such as germanium or silicon germanium, and the semiconductor layers 14B on the substrate 20L are formed of a semiconductor material suitable for n-type devices, such as silicon or carbon-doped silicon. In some embodiments, the semiconductor layers 14B on the substrate 20L are formed of a semiconductor material suitable for p-type devices, such as germanium or silicon germanium, and the semiconductor layers 14B on the substrate 20U are formed of a semiconductor material suitable for n-type devices, such as silicon or carbon-doped silicon.

The semiconductor material(s) of the semiconductor layers 14B are different from and have a high etching selectivity to the semiconductor materials of the dummy semiconductor layers 14A and 14C. As such, the materials of the dummy semiconductor layers 14A and 14C may be removed at a faster rate than the material of the semiconductor layers 14B in subsequent processing. Further, the semiconductor material of the dummy semiconductor layer 14C has a high etching selectivity to the semiconductor material(s) of the dummy semiconductor layers 14A. As such, the material of the dummy semiconductor layer 14C may be selectively removed in subsequent process steps without completely removing materials of the dummy semiconductor layer 14A. In some embodiments, dummy semiconductor layers 14A are formed of silicon germanium, the semiconductor layers 14B are formed of silicon, and the dummy semiconductor layer 14C may be formed of germanium or silicon germanium with a higher germanium atomic percentage than the dummy semiconductor layers 14A. In some embodiments, the dummy semiconductor layers 14A comprise silicon germanium with a germanium concentration in a range of 15% to 25%, and the dummy semiconductor layers 14C comprise silicon germanium with a germanium concentration in a range of 35% to 55%. It has been observed that by controlling the germanium concentrations of the

The multi-layer stacks 14L and 14U are illustrated as including a specific number of the dummy semiconductor layers 14A, 14C and the semiconductor layers 14B. It should be appreciated that the multi-layer stacks 14L and 14U may include any number of the dummy semiconductor layers 14A, 14C and/or the semiconductor layers 14B. For example, FIGS. 2A and 2B the multi-layer stack 14L have a greater number of alternating dummy semiconductor layers 14A and semiconductor layers 14B than the multi-layer stack 14U. However, in other embodiments the multi-layer stack 14L may have a fewer number or an equal number of alternating dummy semiconductor layers 14A and semiconductor layers 14B than the multi-layer stack 14U. The exact number of alternating dummy semiconductor layers 14A and semiconductor layers 14B for each of the multi-layer stacks 14U, 14L may be selected based on a respective device type and/or design of the resulting transistor. Further, the exact arrangement of layers in each of the multi-layer stacks 14U and 14L may be modified depending on device design. For example, FIGS. 2A and 2B illustrate each of the dummy semiconductor layers 14C being in direct contact with a bottommost semiconductor layer 14B. In other embodiments, a dummy semiconductor layer 14A may be disposed between the bottommost semiconductor layer 14B and the dummy semiconductor layer 14C in the multi-layer stacks 14U and/or 14L.

As further illustrated by FIGS. 2A and 2B, bonding layers 18L and 18U are deposited over the substrates 20L and 20U, respectively. Specifically, the bonding layer 18L may be deposited over the multi-layer stack 14L on the substrate 20L, and the bonding layer 18U may be deposited over multi-layer stack 14U on the substrate 20U. The bonding layers 18L and 18U may be deposited by any suitable process, such as physical vapor deposition (PVD), CVD, ALD, or the like. The bonding layers 18L and 18U may facilitate the bonding of the lower substrate 20L to the upper substrate 20U in subsequent processes (see FIG. 3). The bonding layers 18L and 18U may each comprise an insulating material that is suitable for a subsequent dielectric-to-dielectric bonding process. Example materials for the bonding layers 18L and 18U include silicon oxide (e.g., SiO2), silicon nitride, silicon oxynitride, silicon carbonitride, silicon oxycarbonitride, or the like. A material composition of the bonding layer 18L may be the same as or different than a material composition of the bonding layer 18U, and a thickness of the bonding layer 18L and a thickness of the bonding layer 18U may be equal to or different from each other.

In FIG. 3, the upper substrate 20U, having the multi-layer stack 14U and the bonding layer 18U disposed thereon, is flipped over and bonded to the lower substrate 20L, having the multi-layer stack 14L and the bonding layer 18L disposed thereon. The bonded structure includes, in the following order, the lower substrate 20L; the multi-layer stack 14L; the bonding layer 18L; the bonding layer 18U; the multi-layer stack 14U; and the upper substrate 20U. Specifically, the bonding layers 18L and 18U may be bonded together using a suitable technique, such as dielectric-to-dielectric bonding, or the like. After bonding, the lower bonding layer 18L and the upper bonding layer 18U may be collectively referred to as a bonded layer 18. The bonded layer 18 may or may not have an interface disposed therein where the bonding layer 18L meets the bonding layer 18U.

In some embodiments, the dielectric-to-dielectric bonding process includes applying a surface treatment to one or more of the bonding layers 18L and 18U to form hydroxyl (OH) groups at exposed surfaces of the bonding layers 18L and 18U. The surface treatment may include a plasma treatment, such as a nitrogen (N₂) plasma treatment. After the plasma treatment, the surface treatment may further include a cleaning process that may be applied to one or more of the bonding layers 18L and 18U. The bonding layer 18U may then be placed over and aligned to the bonding layer 18L. The two bonding layers 18L and 18U are then pressed against each other to initiate a pre-bonding of the upper substrate 20U to the lower substrate 20L. The pre-bonding be performed at room temperature (e.g., in a range of 20° C. to 28° C.). After the pre-bonding, an annealing process may be applied by, for example, heating the substrates 20L and 20U to a temperature of in a range of 300° C. to 500° C. The annealing process drives triggers the formation of covalent bonds between the bonding layers 18L and 18U.

In FIG. 4, the substrate 20U may be at least partially removed. Removing the substrate 20U may be include a thinning process to remove the bulk of the substrate 20U. The thinning process may include a grinding process, a chemical mechanical polish (CMP), one or more etch back process(es), combinations thereof, or the like. The one or more etch back process(es) may include dry etching processes, wet etching processes, combination thereof, or the like.

FIG. 4 illustrates embodiments where the substrate 20U is completely removed, exposing the dummy semiconductor layer 14C of the upper multi-layer stack 14U. Alternatively, a portion of the substrate 20U may remain over the dummy semiconductor layer 14C during subsequent patterning processes (e.g., fin patterning, see FIG. 5), and the remaining portions of the substrate 20U may be removed after the patterning processes (e.g., after the fins are patterned and prior to forming dummy gate stacks). In such embodiments, the remaining portions of the substrate 20U may act as an additional protective layer over the dummy semiconductor layer 14C during the fin patterning process.

In FIG. 5, the multi-layer stack 14U, the bonded layer 18, the multi-layer stack 14L, and the substrate 20L are patterned to form semiconductor strips 28 extending upwards from the substrate 20L. Each of semiconductor strips 28 includes semiconductor strip 20′ (patterned portions of the substrate 20L) and a multi-layer stack 22. Each multi-layer stack 22 includes dummy nanostructures 24A patterned from a material of the dummy semiconductor layer 14A; dummy nanostructures 24B patterned from a material of the dummy semiconductor layer 14C; dielectric isolation structures 56 patterned from a material of the bonded layer 18; lower semiconductor nanostructures 26L patterned from semiconductor layers 14B in the multi-layer stack 14L; and upper semiconductor nanostructures 26U patterned from semiconductor layers 14B in the multi-layer stack 16U (see FIG. 4). The dummy nanostructures 24B may be arranged as a topmost (e.g., above the upper semiconductor nanostructures 26U) and bottommost (e.g., under the lower semiconductor nanostructures 26L) structures in each of the multi-layer stacks 22. In subsequent process steps, the dummy nanostructures 24B may be replaced with insulating, protective structures that provide etch/CMP stop layers for subsequently formed gate stacks and/or backside gate contacts.

The lower semiconductor nanostructures 26L will provide channel regions for lower nanostructure-FETs of the stacking transistors. The upper semiconductor nanostructures 26U will provide channel regions for upper nanostructure-FETs of the stacking transistors. Dielectric isolation structures 56 are used to isolate the upper semiconductor nanostructures 26U (collectively) from the lower semiconductor nanostructures 26L (collectively). Because the dielectric isolation structures 56 are patterned from the bonded layer 18, a physical interface (e.g., remaining interfaces between the bonding layers 18U and 18L) may remain in an interior region of the dielectric isolation structures 56. Further, middle semiconductor nanostructures (ones of the semiconductor nanostructures 26 in contact with the dielectric isolation structures 56) and the dielectric isolation structures 56 may define the boundaries of the lower nanostructure-FETs and the upper nanostructure-FETs. For example, the semiconductor nanostructures 26 that are immediately above/below (e.g., in contact with) the dummy nanostructures 24B may be used for isolation and may or may not act as channel regions for the stacking transistors. Dummy nanostructures 24A and dummy nanostructures 24B may further be collectively referred to as dummy nanostructures 24, and the lower semiconductor nanostructures 26L and the upper semiconductor nanostructures 26U may further be collectively referred to as semiconductor nanostructures 26.

The semiconductor fins and the nanostructures may be patterned by any suitable method. For example, the patterning process may include one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used as an etching mask for the patterning process to etch the layers of the first, second, and third semiconductor materials and the semiconductor layer 20. The etching may be performed by any acceptable etch process, such as a Reactive Ion Etch (RIE), Neutral Beam Etch (NBE), the like, or a combination thereof. The etching may be anisotropic.

As also illustrated by FIG. 5, STI regions 32 are formed over the semiconductor layer 20 and between adjacent semiconductor strips 28. STI regions 32 may include a dielectric liner and a dielectric material over the dielectric liner. Each of the dielectric liner and the dielectric material may include an oxide such as silicon oxide, a nitride, such as silicon nitride, the like, or a combination thereof. The formation of the STI regions 32 may include depositing the dielectric layer(s), and performing a planarization process such as a Chemical Mechanical Polish (CMP) process, a mechanical polishing process, or the like to remove excess portions of the dielectric materials. The deposition processes may include ALD, High-Density Plasma CVD (HDP-CVD), Flowable CVD (FCVD), the like, or a combination thereof. In some embodiments, the STI regions 32 include silicon oxide formed by an FCVD process, followed by an anneal process. Then, the dielectric layers(s) are recessed to define the STI regions 32. The dielectric layer(s) maybe recessed such that upper portions of semiconductor strips 28 (including multi-layer stacks 22 and the ESL 16) protrude higher than the remaining STI regions 32.

After the STI regions 32 are formed, dummy gate stacks 42 may be formed over and along sidewalls of the upper portions of the semiconductor strips 28 (the portions that protrude higher than the STI regions 32). Forming the dummy gate stacks 42 may include forming dummy dielectric layer 36 on the semiconductor strips 28. Dummy dielectric layer 36 may be formed of or comprise, for example, silicon oxide, silicon nitride, a combination thereof, or the like, and may be deposited or thermally grown according to acceptable techniques. A dummy gate layer 38 is formed over the dummy dielectric layer 36. The dummy gate layer 38 may be deposited, for example, through Physical Vapor Deposition (PVD), CVD, or other techniques, and then planarized, such as by a CMP process. The material of dummy gate layer 38 be conductive or non-conductive, and may be selected from a group including amorphous silicon, polycrystalline-silicon (polysilicon), poly-crystalline silicon-germanium (poly-SiGe), or the like. A mask layer 40 is formed over the planarized dummy gate layer 38, and may include, for example, silicon nitride, silicon oxynitride, or the like. Next, the mask layer 40 may be patterned through photolithography and etching processes to form a mask, which is then used to etch and pattern dummy gate layer 38, and possibly the dummy dielectric layer 36. The remaining portions of mask layer 40, dummy gate layer 38, and dummy dielectric layer 36 form dummy gate stacks 42.

In FIG. 6, gate spacers 44 are formed along sidewalls of the dummy gate stacks 42. The gate spacers 44 may be formed by conformally forming one or more dielectric layers and subsequently etching the dielectric layers anisotropically. The applicable dielectric materials may include silicon oxide, silicon nitride, silicon oxynitride, silicon oxycarbonitride, or the like, which may be formed by a deposition process such as CVD, ALD, or the like.

Subsequently, source/drain recesses 46 are formed in semiconductor strips 28. The source/drain recesses 46 are formed through etching, and may extend through the multi-layer stacks 22, through the ESL 16, and into the semiconductor strips 20′. The bottom surfaces of the source/drain recesses 46 may be at a level above, below, or level with the top surfaces of the isolation regions 32. In the etching processes, the gate spacers 44 and the dummy gate stacks 42 mask some portions of the semiconductor strips 28. The etching may include a single etch process or multiple etch processes. Timed etch processes may be used to stop the etching of the source/drain recesses 46 upon source/drain recesses 46 reaching a desired depth.

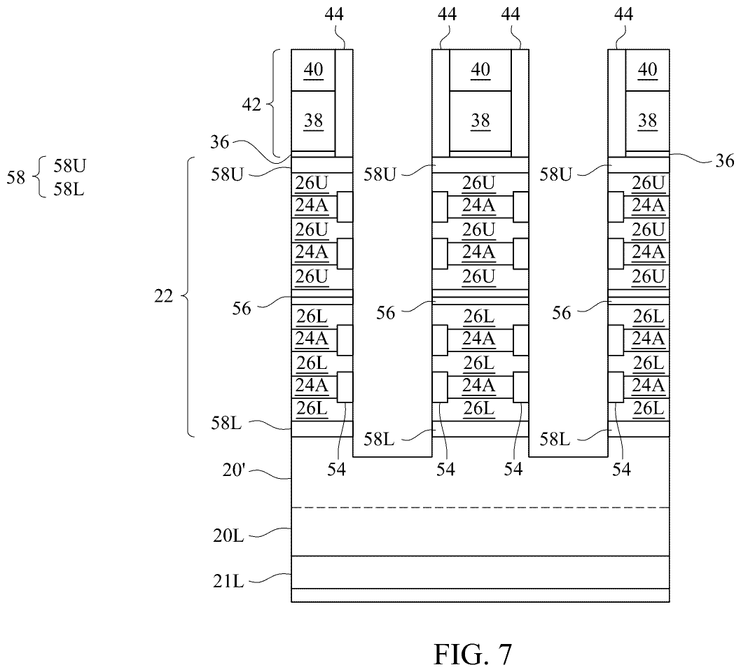

In FIG. 7, inner spacers 54 and insulating protective structures 58 are formed. Forming inner spacers 54 and insulating protective structures 58 may include an etching process that laterally etches the dummy nanostructures 24A and removes the dummy nanostructure 24B. The etching process may be isotropic and may be selective to the material of the dummy nanostructures 24, so that the dummy nanostructures 24 are etched at a faster rate than the semiconductor nanostructures 26. The etching process may also be selective to the material of the dummy nanostructures 24B, so that the dummy nanostructures 24B are etched at a faster rate than the dummy nanostructures 24A. In this manner, the dummy nanostructures 24B may be completely removed from under the lower semiconductor nanostructures 26L (collectively) and from over the upper semiconductor nanostructures 26U (collectively) without completely removing the dummy nanostructures 24A. In some embodiments, the etching process may etch the semiconductor nanostructures 26 slightly such that edge portions of the semiconductor nanostructures 26 are thinner than center portions of the semiconductor nanostructures 26.

In some embodiments where the dummy nanostructures 24B are formed of germanium or silicon germanium with a high germanium atomic percentage, the dummy nanostructures 24A are formed of silicon germanium with a low germanium atomic percentage, and the semiconductor nanostructures 26 are formed of silicon free from germanium, the etch process may comprise a dry etch process using chlorine gas, with or without a plasma. Because the dummy gate stacks 42 warp around sidewalls of the semiconductor nanostructures 26 (see FIG. 5), the dummy gate stacks 42 may support the semiconductor nanostructures 26 so that the semiconductor nanostructures 26 do not collapse upon removal of the dummy nanostructures 24B. Further, although sidewalls of the dummy nanostructures 24A are illustrated as being straight after the etching, the sidewalls may be concave or convex.

Inner spacers 54 are formed on sidewalls of the recessed dummy nanostructures 24A, and insulating protective structures 58 are formed over the upper semiconductor nanostructures 26U (collectively) and under the lower semiconductor nanostructures 26L (collectively). Specifically, upper insulating protective structures 58U are formed over the upper semiconductor nanostructures 26U (collectively), and lower insulating protective structures 58L are formed under the lower semiconductor nanostructures 26L (collectively). As subsequently described in greater detail, source/drain regions will be subsequently formed in the source/drain recesses 46, and the dummy nanostructures 24A will be replaced with corresponding gate structures. The inner spacers 54 act as isolation features between the subsequently formed source/drain regions and the subsequently formed gate structures. Further, the inner spacers 54 may be used to prevent damage to the subsequently formed source/drain regions by subsequent etch processes, such as the etch processes used to form gate structures. The insulating protective structures 58, on the other hand, are used as etch stop layers. For example, the lower insulating protective structures 58L may provide an etch stop layer for subsequently formed backside gate contacts to a lower gate structure of the stacking transistor. As another example, the upper insulating protective structures 58U may provide an etch stop layer to allow for the upper gate electrodes 80U (see FIGS. 9A and 9B) to be etched back.

The inner spacers 54 and the insulating protective structures 58 may be formed by conformally depositing an insulating material in the source/drain recesses 46, on sidewalls of the dummy nanostructures 56A, and between the upper and lower semiconductor nanostructures 26U and 26L, and then etching the insulating material. The insulating material may be a hard dielectric material, such as silicon nitride, silicon oxynitride, a carbon-containing dielectric material (e.g., silicon oxycarbonitride, silicon oxycarbide, silicon carbonitride, or the like), a boron-containing dielectric material (e.g., boron nitride, boron carbonitride, or the like), or the like. Other low-dielectric constant (low-k) materials having a k-value less than about 3.5 may be utilized. The insulating material may be formed by a deposition process, such as ALD, CVD, or the like. The etching of the insulating material may be anisotropic or isotropic. The insulating material, when etched, has portions remaining in the sidewalls of the dummy nanostructures 26A (thus forming the inner spacers 54) and has portions remaining over/under the upper and lower semiconductor nanostructures 26U and 26L (thus forming the insulating protective structures 58). As described, the inner spacers 54 and the insulating protective structures 58 are formed concurrently and thus have a same material composition. Alternatively, the inner spacers 54 may be formed in a separate process (e.g., prior to or after) as forming the insulating protective structures 58. In such embodiments, the inner spacers 54 may have a same material composition or a different material composition as the insulating protective structures 58.

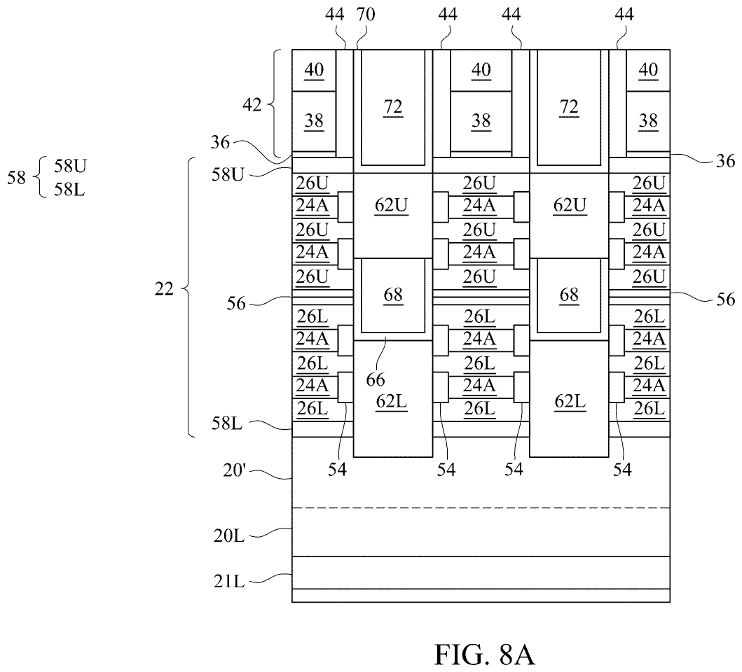

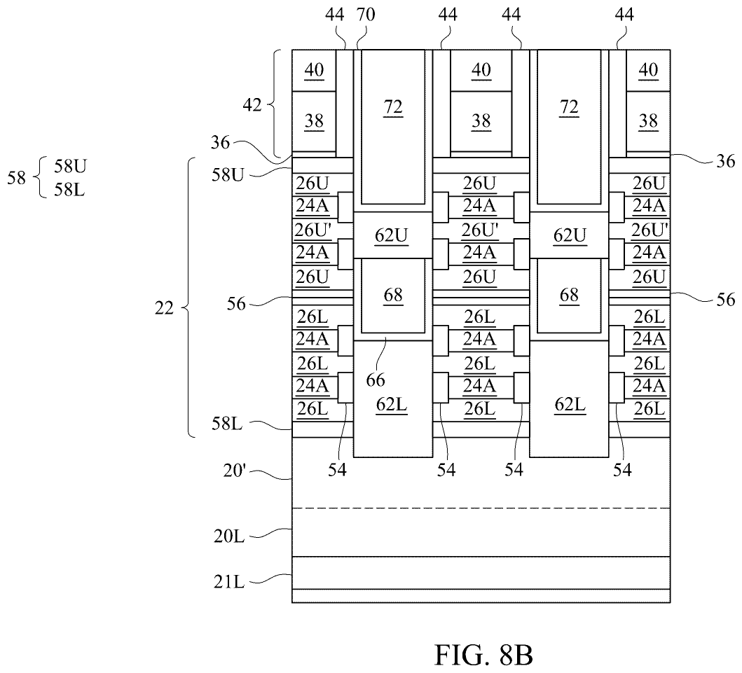

In FIG. 8A, lower and upper epitaxial source/drain regions 62L and 62U are formed. The lower epitaxial source/drain regions 62L are formed in the lower portions of the source/drain recesses 46. The lower epitaxial source/drain regions 62L are in contact with the lower semiconductor nanostructures 26L and are not in contact with the upper semiconductor nanostructures 26U. Inner spacers 54 electrically insulate the lower epitaxial source/drain regions 62L from the dummy nanostructures 24A, which will be replaced with replacement gates in subsequent processes.

The lower epitaxial source/drain regions 62L are epitaxially grown, and have a conductivity type that is suitable for the device type (p-type or n-type) of the lower nanostructure-FETs. When lower epitaxial source/drain regions 62L are n-type source/drain regions, the respective material may include silicon or carbon-doped silicon, which is doped with an n-type dopant such as phosphorous, arsenic, or the like. When lower epitaxial source/drain regions 62L are p-type source/drain regions, the respective material may include silicon or silicon germanium, which is doped with a p-type dopant such as boron, indium, or the like. The lower epitaxial source/drain regions 62L may be in-situ doped, and may be, or may not be, implanted with the corresponding p-type or n-type dopants. During the epitaxy of the lower epitaxial source/drain regions 62L, the upper semiconductor nanostructures 26U may be masked to prevent undesired epitaxial growth on the upper semiconductor nanostructures 26U. After the lower epitaxial source/drain regions 62L are grown, the masks on the upper semiconductor nanostructures 26U may then be removed.

As a result of the epitaxy processes used for forming the lower epitaxial source/drain regions 62L, upper surfaces of the lower epitaxial source/drain regions 62L have facets which expand laterally outward beyond sidewalls of the multi-layer stacks 22. In some embodiments, adjacent lower epitaxial source/drain regions 62L remain separated after the epitaxy process is completed. In other embodiments, these facets cause neighboring lower epitaxial source/drain regions 62L of a same FET to merge.

A first contact etch stop layer (CESL) 66 and a first ILD 68 are formed over the lower epitaxial source/drain regions 62L. The first CESL 66 may be formed of a dielectric material having a high etching selectivity from the etching of the first ILD 68, such as silicon nitride, silicon oxide, silicon oxynitride, or the like, which may be formed by any suitable deposition process, such as CVD, ALD, or the like. The first ILD 68 may be formed of a dielectric material, which may be deposited by any suitable method, such as CVD, plasma-enhanced CVD (PECVD), or FCVD. The applicable dielectric material of the first ILD 68 may include phospho-silicate glass (PSG), boro-silicate glass (BSG), boron-doped phospho-silicate glass (BPSG), undoped silicate glass (USG), silicon oxide, or the like.

The formation processes may include depositing a conformal CESL layer, depositing a material for the first ILD 68, followed by a planarization process and then an etch-back process. In some embodiments, the first ILD 68 is etched first, leaving the first CESL 66 unetched. An anisotropic etching process is then performed to remove the portions of the first CESL 66 higher than the recessed first ILD 68. After the recessing, the sidewalls of the upper semiconductor nanostructures 26U are exposed.

Upper epitaxial source/drain regions 62U are then formed in the upper portions of the source/drain recesses 46. The upper epitaxial source/drain regions 62U may be epitaxially grown from exposed surfaces of the upper semiconductor nanostructures 26U. The materials of upper epitaxial source/drain regions 62U may be selected from the same candidate group of materials for forming lower source/drain regions 62L, depending on the desired conductivity type of upper epitaxial source/drain regions 62U. In embodiments where the stacking transistors are CFETs, the conductivity type of the upper epitaxial source/drain regions 62U may be opposite the conductivity type of the lower epitaxial source/drain regions 62L. For example, the upper epitaxial source/drain regions 62U may be oppositely doped from the lower epitaxial source/drain regions 62L. The upper epitaxial source/drain regions 62U may be in-situ doped, and/or may be implanted, with an n-type or p-type dopant. Adjacent upper source/drain regions 62U may remain separated after the epitaxy process or may be merged. Further, volumes of the upper epitaxial source/drain regions 62U may be the same as, equal to, or less than the lower epitaxial source/drain regions 62L.

After the upper epitaxial source/drain regions 62U are formed, a second CESL 70 and a second ILD 72 are formed. The materials and the formation methods may be similar to the materials and the formation methods of first CESL 66 and first ILD 68, respectively, and are not discussed in detail herein. The formation process may include depositing the layers for CESL 70 and ILD 72, and performing a planarization process to remove the excess portion of the corresponding layers. After the planarization process, top surfaces of the second ILD 72, the gate spacers 44, and the dummy gate stacks 42 are coplanar (within process variations). The planarization process may remove masks 40, or leave hard masks 40 unremoved.

FIG. 8A illustrates the upper epitaxial source/drain regions 62U as contacting a topmost nanostructure of the upper semiconductor nanostructures 26U, such as the upper semiconductor nanostructures 26U that directly adjoins the upper insulating protective structures 58U. Alternatively, the topmost nanostructure of the upper semiconductor nanostructures 26U may be a dummy nanostructure, and the upper epitaxial source/drain regions 62U may not contact the topmost nanostructure of the upper semiconductor nanostructures 26U as illustrated by FIG. 8B. As illustrated by FIG. 8B, the upper epitaxial source/drain regions 62U may only contact middle ones (labeled 26U′) of the upper semiconductor nanostructures. In such embodiments, the topmost and bottommost nanostructures of the upper semiconductor nanostructures 26U are dummy nanostructures. Subsequent FIGS. 9A through 12 illustrate additional processing steps performed on the embodiment of FIG. 8A, but it should be understood that these processing steps can be applied to the embodiment of FIG. 8B as well.

FIGS. 9A and 9B illustrate different cross-sections of a replacement gate process to replace the dummy gate stacks 42 and the dummy nanostructures 24A with gate stacks 90. FIG. 9A illustrates a cross-sectional view along reference line A-A′ of FIG. 1; and FIG. 9B illustrates a cross-sectional view along reference line B-B′ of FIG. 1. The replacement gate process includes first removing the dummy gate stacks 42 and the remaining portions of the dummy nanostructures 24A. The dummy gate stacks 42 are removed in one or more etching processes, so that recesses are defined between the gate spacers 44 and the upper portions of the semiconductor strips 28 are exposed. The remaining portions of the dummy nanostructures 24A are then removed through etching, so that the recesses extend between the semiconductor nanostructures 26. In the etching process, the dummy nanostructures 24A is etched at a faster rate than the semiconductor nanostructures 26, the dielectric isolation structures 56, the insulating protective structures 58, the inner spacers 54, and the ESL 16. The etching may be isotropic. For example, when the dummy nanostructures 24A are formed of silicon-germanium, and the semiconductor nanostructures 26 are formed of silicon, the etch process may include a wet etch process using tetramethylammonium hydroxide (TMAH), ammonium hydroxide (NH₄OH), or the like.

Then, gate dielectrics 78 are deposited in the recesses between the gate spacers 44 and on the exposed semiconductor nanostructures 26. The gate dielectrics 78 are conformally formed on the exposed surfaces of the recesses (the removed dummy gate stacks 42 and the dummy nanostructures 24A) including the semiconductor nanostructures 26 and the gate spacers 44. In some embodiments, the gate dielectrics 78 wrap around all (e.g., four) sides of the semiconductor nanostructures 26. Specifically, the gate dielectrics 78 may be formed on the top surfaces of the semiconductor strips 20′; on the top surfaces, the sidewalls, and the bottom surfaces of the semiconductor nanostructures 26; and on the sidewalls of the gate spacers 44. The gate dielectrics 78 may include an oxide such as silicon oxide or a metal oxide, a silicate such as a metal silicate, combinations thereof, multi-layers thereof, or the like. The gate dielectrics 78 may include a high-dielectric constant (high-k) material having a k-value greater than about 7.0, such as a metal oxide or a silicate of hafnium, aluminum, zirconium, lanthanum, manganese, barium, titanium, lead, and combinations thereof. The formation methods of the gate dielectrics 78 may include molecular-beam deposition (MBD), ALD, PECVD, and the like followed by a planarization process (e.g., a CMP) to remove portions of the gate dielectrics 78 above the second ILD 72. Although single-layered gate dielectrics 78 are illustrated, the gate dielectrics 78 may include multiple layers, such as an interfacial layer and an overlying high-k dielectric layer.

Lower gate electrodes 80L are formed on the gate dielectrics 78 around the lower semiconductor nanostructures 26L. For example, the lower gate electrodes 80L wrap around the lower semiconductor nanostructures 26L. The lower gate electrodes 80L may be formed of a metal-containing material such as tungsten, titanium, titanium nitride, tantalum, tantalum nitride, tantalum carbide, aluminum, ruthenium, cobalt, combinations thereof, multi-layers thereof, or the like. Although single-layered gate electrodes are illustrated, the lower gate electrodes 80L may include any number of work function tuning layers, any number of barrier layers, any number of glue layers, and a fill material.

The lower gate electrodes 80L are formed of material(s) that are suitable for the device type of the lower nanostructure-FETs. For example, the lower gate electrodes 80L may include one or more work function tuning layer(s) formed of material(s) that are suitable for the device type of the lower nanostructure-FETs. In some embodiments, the lower gate electrodes 80L include an n-type work function tuning layer, which may be formed of titanium aluminum, titanium aluminum carbide, tantalum aluminum, tantalum carbide, combinations thereof, or the like. In some embodiments, the lower gate electrodes 80L include a p-type work function tuning layer, which may be formed of titanium nitride, tantalum nitride, combinations thereof, or the like. Additionally or alternatively, the lower gate electrodes 80L may include a dipole-inducing element that is suitable for the device type of the lower nanostructure-FETs. Acceptable dipole-inducing elements include lanthanum, aluminum, scandium, ruthenium, zirconium, erbium, magnesium, strontium, and combinations thereof.

The lower gate electrodes 80L may be formed by conformally depositing one or more gate electrode layer(s) recessing the gate electrode layer(s). Any acceptable etch process, such as a dry etch, a wet etch, the like, or a combination thereof, may be performed to recess the gate electrode layer(s). The etching may be isotropic. Etching the lower gate electrodes 80L may expose the upper semiconductor nanostructures 26U.

In some embodiments, isolation layers (not explicitly illustrated) may be optionally formed on the lower gate electrodes 80L. The isolation layers act as isolation features between the lower gate electrodes 80L and subsequently formed upper gate electrodes 80U. The isolation layers may be formed by conformally depositing a dielectric material (e.g., silicon oxide, silicon nitride, silicon oxynitride, silicon oxycarbonitride, combinations thereof, or the like) and subsequently recessing the dielectric material to expose the upper semiconductor nanostructures 26U.

Then, upper gate electrodes 80U are formed on the isolation layers described above (if present) or the lower gate electrodes 80L. The upper gate electrodes 80U are disposed between the upper semiconductor nanostructures 26U. In some embodiments, the upper gate electrodes 80U wrap around the upper semiconductor nanostructures 26U. The upper gate electrodes 80U may be formed of the same candidate materials and candidate processes for forming the lower gate electrodes 80L. The upper gate electrodes 80U are formed of material(s) that are suitable for the device type of the upper nanostructure-FETs. For example, the upper gate electrodes 80U may include one or more work function tuning layer(s) formed of material(s) that are suitable for the device type of the upper nanostructure-FETs. Although single-layered gate electrodes 80U are illustrated, the upper gate electrodes 80U may include any number of work function tuning layers, any number of barrier layers, any number of glue layers, and a fill material.

Additionally, a removal process is performed to level top surfaces of the upper gate electrodes 80U and upper insulating protective structures 58U. The removal process for forming the gate dielectrics 78 may be the same removal process as the removal process for forming the upper gate electrodes 80U. In some embodiments, a planarization process such as CMP, an etch-back process, combinations thereof, or the like may be utilized. After the planarization process, the top surfaces of the upper gate electrodes 80U, the gate dielectrics 78, the second ILD 72, and the gate spacers 44 are substantially coplanar (within process variations). The upper insulating protective structures 58U may act as an etch stop layer/CMP stop layer during the removal process. For example, the upper insulating protective structures 58U may mask (e.g., protect) the underlying semiconductor nanostructures 26 while the upper gate electrode 80U is thinned, thereby allowing more of the upper gate electrodes 80U to be removed without damaging the semiconductor nanostructures 26. As a resulting, the overall gate height of the upper gate structures 90U to be reduced without additional manufacturing defects. Reducing the height of the upper gate structures 90U may have advantages, such as reduced capacitance and improved device performance.

Each respective pair of a gate dielectric 78 and a gate electrode 80 (including an upper gate electrode 80U and/or a lower gate electrode 80L) may be collectively referred to as a “gate structure” 90 (including upper gate structures 90U and lower gate structures 90L). Each gate structure 90 extends along three sides (e.g., a top surface, a sidewall, and a bottom surface) of a channel region of a semiconductor nanostructure 26 (see FIG. 1 and FIG. 9B). The lower gate structures 90L may also extend along sidewalls of the lower insulating protective structures 58L and along sidewalls of the semiconductor strips 20′ (see FIG. 9B), and the upper gate structures 90U may extend along sidewalls of the upper insulating protective structures 58U.

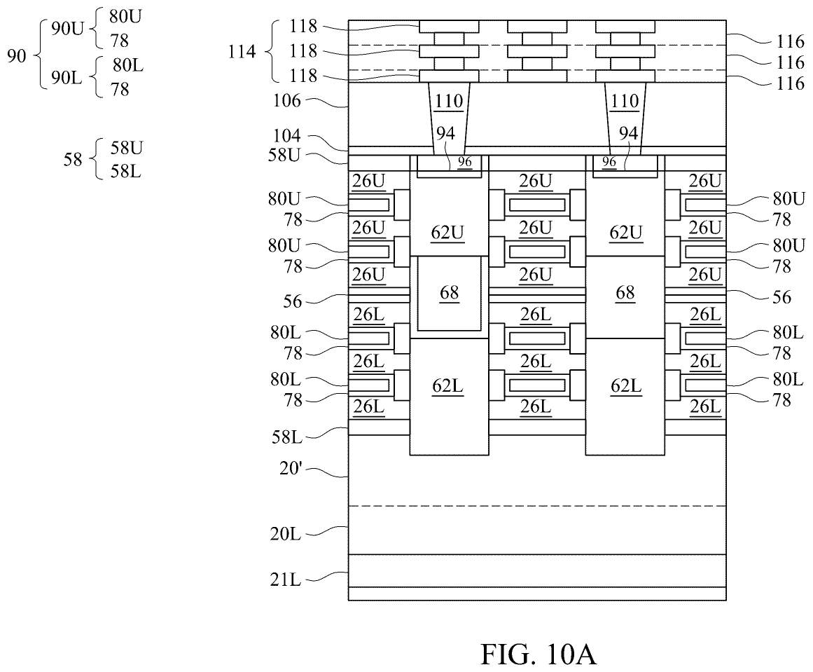

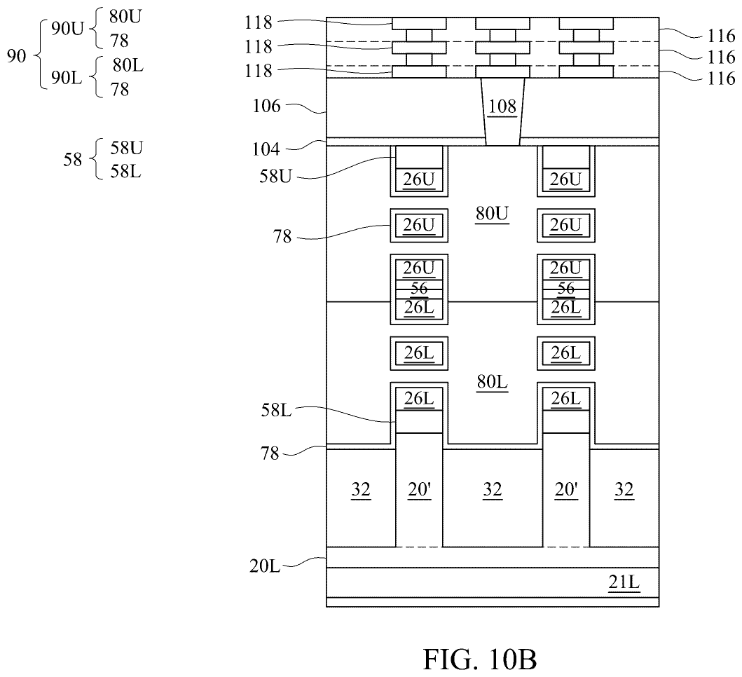

In FIGS. 10A and 10B, metal-semiconductor alloy regions 94 and source/drain contacts 96 are formed through the second ILD 72 to electrically couple to the upper epitaxial source/drain regions 62U and/or the lower epitaxial source/drain regions 62L. As an example to form the source/drain contacts 96, openings are formed through the second ILD 72 and the second CESL 70 using acceptable photolithography and etching techniques. A liner (not separately illustrated), such as a diffusion barrier layer, an adhesion layer, or the like, and a conductive material are formed in the openings. The liner may include titanium, titanium nitride, tantalum, tantalum nitride, or the like. The conductive material may be cobalt, tungsten, copper, a copper alloy, silver, gold, aluminum, nickel, or the like. A removal process may be performed to remove excess material from the top surfaces of the gate spacers 44 and the second ILD 72. The remaining liner and conductive material form the source/drain contacts 96 in the openings. In some embodiments, a planarization process such as a CMP, an etch-back process, combinations thereof, or the like is utilized. After the planarization process, the top surfaces of the gate spacers 44, the second ILD 72, and the source/drain contacts 96 are substantially coplanar (within process variations).

Optionally, metal-semiconductor alloy regions 94 are formed at the interfaces between the source/drain regions 62 and the source/drain contacts 96. The metal-semiconductor alloy regions 94 can be silicide regions formed of a metal silicide (e.g., titanium silicide, cobalt silicide, nickel silicide, etc.), germanide regions formed of a metal germanide (e.g. titanium germanide, cobalt germanide, nickel germanide, etc.), silicon-germanide regions formed of both a metal silicide and a metal germanide, or the like. The metal-semiconductor alloy regions 94 can be formed before the material(s) of the source/drain contacts 96 by depositing a metal in the openings for the source/drain contacts 96 and then performing a thermal anneal process. The metal can be any metal capable of reacting with the semiconductor materials (e.g., silicon, silicon-germanium, germanium, etc.) of the source/drain regions 62 to form a low-resistance metal-semiconductor alloy, such as nickel, cobalt, titanium, tantalum, platinum, tungsten, other noble metals, other refractory metals, rare earth metals or their alloys. The metal can be deposited by a deposition process such as ALD, CVD, PVD, or the like. After the thermal anneal process, a cleaning process, such as a wet clean, may be performed to remove any residual metal from the openings for the source/drain contacts 96, such as from surfaces of the metal-semiconductor alloy regions 94. The material(s) of the source/drain contacts 96 can then be formed on the metal-semiconductor alloy regions 94.

An ESL 104 and a third ILD 106 are then formed. In some embodiments, The ESL 104 may include a dielectric material having a high etching selectivity from the etching of the third ILD 106, such as, aluminum oxide, aluminum nitride, silicon oxycarbide, or the like. The third ILD 106 may be formed using flowable CVD, ALD, or the like, and the material may include PSG, BSG, BPSG, USG, or the like, which may be deposited by any suitable method, such as CVD, PECVD, or the like.

Subsequently, gate contacts 108 (see FIG. 10B) and source/drain vias 110 (see FIG. 10A) are formed to contact the upper gate electrodes 80U and the source/drain contacts 96, respectively. As an example to form the gate contacts 108 and the source/drain vias 110, openings for the gate contacts 108 and the source/drain vias 110 are formed through the third ILD 106 and the ESL 104. The openings may be formed using acceptable photolithography and etching techniques. A liner (not separately illustrated), such as a diffusion barrier layer, an adhesion layer, or the like, and a conductive material are formed in the openings. The liner may include titanium, titanium nitride, tantalum, tantalum nitride, or the like. The conductive material may be cobalt, tungsten, copper, a copper alloy, silver, gold, aluminum, nickel, or the like. A planarization process, such as a CMP, may be performed to remove excess material from the top surface of the third ILD 106. The remaining liner and conductive material form the gate contacts 108 and the source/drain vias 110 in the openings. The gate contacts 108 and the source/drain vias 110 may be formed in distinct processes, or may be formed in the same process. As illustrated, the gate contacts 108 and the source/drain vias 110 may be formed in different cross-sections, which may avoid shorting of the contacts.

A front-side interconnect structure 114 is formed on the device layer 112. The front-side interconnect structure 114 includes dielectric layers 116 and layers of conductive features 118 in the dielectric layers 116. The dielectric layers 116 may include low-k dielectric layers formed of low-k dielectric materials. The dielectric layers 116 may further include passivation layers, which are formed of non-low-k and dense dielectric materials such as Undoped Silicate-Glass (USG), silicon oxide, silicon nitride, or the like, or combinations thereof over the low-k dielectric materials. The dielectric layers 116 may also include polymer layers.

The conductive features 118 may include conductive lines and vias, which may be formed using damascene processes. Conductive features 118 may include metal lines and metal vias, which includes diffusion barriers and a copper containing material over the diffusion barriers. There may also be aluminum pads over and electrically connected to the metal lines and vias. As will be explained in greater detail below, contacts to the lower gate stacks 90L and the lower source/drain regions 62L may be made through a backside of the device layer 112 (e.g., a side opposite to the front-side interconnect structure 114).

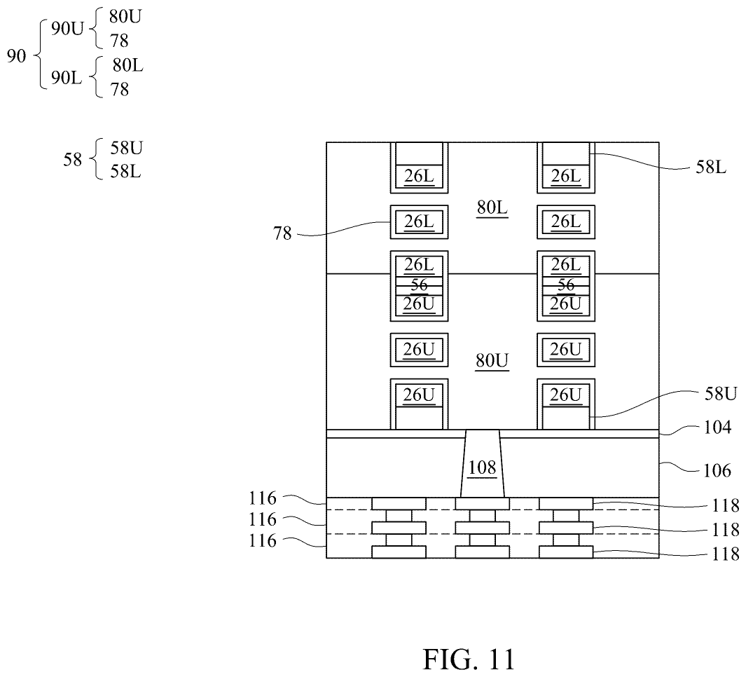

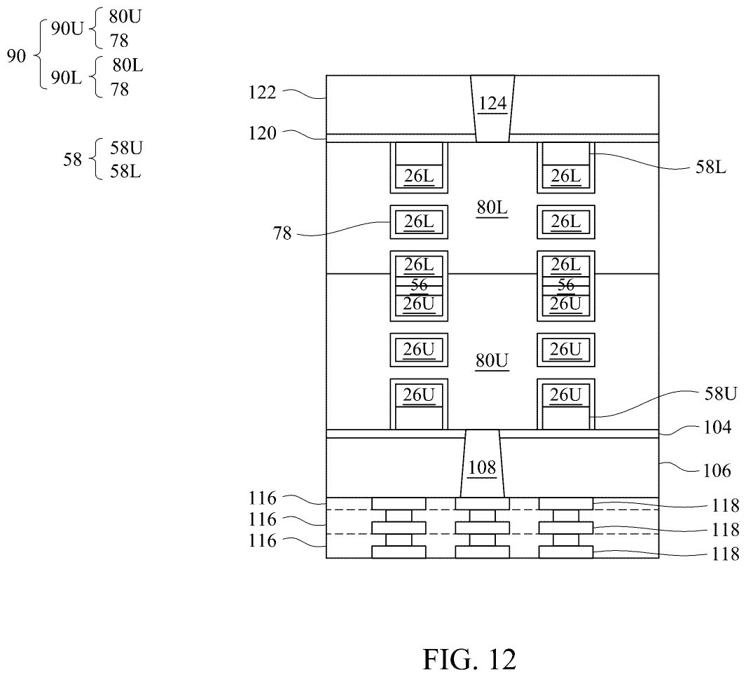

FIGS. 11 and 12 illustrate cross-sectional views of intermediate steps of forming backside gate contacts to the lower gate stacks 90L in accordance with some embodiments. Referring to FIG. 11, an orientation of the device may be flipped. For example, a carrier substrate (not explicitly illustrated) may be bonded to the front-side interconnect structure 114 by dielectric-to-dielectric bonding, and the device may be flipped to expose a backside of the device layer 112 (the side of the device layer 112 opposite to the front-side interconnect structure 114). Then, a planarization process may be performed on the backside of the device layer 112. In some embodiments, the planarization process may include a combination of CMP and/or etch-back processes, for example. The planarization process may remove the lower substrate 20L (see FIG. 4, the semiconductor strips 20′, the STI regions 32, and lateral portions of the gate dielectric 78 (e.g., portions between the STI regions 32 and the lower gate electrode 80L). In some embodiments, the planarization process may include thinning the lower substrate 20L with a CMP, grinding, or the like processes to remove a bulk of the lower substrate 20L. The CMP stop layer 21L may be used as a stopping point of the thinning process to avoid inadvertent damage to the transistor devices. Then, the CMP stop layer 21L may be removed by one or more etching processes, for example. After the CMP stop layer 21L is removed, remaining portions of the lower substrate 20L, the STI regions 32, the semiconductor strips 20′, and the lateral portions of the gate dielectric 78 may be removed by one or more CMP, etch back processes, or the like, thereby exposing the lower gate electrode 80L.

The insulating protective structures 58L may act as CMP stop layers/etch stop layers to provide an accurate stopping point during removal of the remaining portions of the lower substrate 20L, the STI regions 32, the semiconductor strips 20′, and lateral portions of the gate dielectric 78. For example, the insulating protective structures 58 may mask (e.g., protect) the semiconductor nanostructures 26 during the planarization process that removes the remaining portions of the lower substrate 20L, the STI regions 32, the semiconductor strips 20′, and lateral portions of the gate dielectric 78. In this manner, device defects caused by unintentional over etching can be reduced. As illustrated by FIG. 11, lateral surfaces of the insulating protective structures 58L, the gate electrode 80L, and the gate dielectric 78 may be substantially level (within process variations) in the resulting structure.

In FIG. 12, a backside ESL 120 and a backside ILD 122 are sequentially deposited over the backside of the lower gate electrode 80L and the insulating protective structures 58L. The backside ESLs 120 may be formed using similar materials and processes as the front side ESL 104 described above, and the backside ILD 122 may be formed using similar materials and processes as the third ILD 106 described above. In some embodiments, the backside ESL 120 may cover lateral surfaces of the insulating protective structures 58L and the lower gate electrode 80L.

As further illustrated in FIG. 12, backside gate contacts 124 may be formed through the backside ESL 120 and the backside ILD 122. Forming the backside gate contacts 124 may include patterning backside gate contact openings the backside ILD 122 and the backside ESL 120 to expose the lower gate electrode 80L using a combination of lithography and etching process(es).

Subsequently, backside gate contacts 124 are formed in the backside gate contact openings to contact the lower gate electrodes 80L. As an example to form the backside gate contacts 124, a liner (not separately illustrated), such as a diffusion barrier layer, an adhesion layer, or the like, and a conductive material are formed in the backside gate contact openings. The liner may include titanium, titanium nitride, tantalum, tantalum nitride, or the like. The conductive material may be cobalt, tungsten, copper, a copper alloy, silver, gold, aluminum, nickel, or the like. A planarization process, such as a CMP, may be performed to remove excess material from the top surface of the backside ILD 122. The remaining liner and conductive material form the backside gate contacts 124. Further, one or more the backside source/drain vias may be formed to the lower epitaxial source/drain regions 62L (see FIG. 10A). the backside source/drain vias may be formed of a same material and process as the source/drain vias 110 described above. The backside gate contacts 124 and the backside source/drain vias may be formed in distinct processes, or may be formed in the same process. Additional processes, such as the formation of a backside interconnect structure (not explicitly illustrated) similar to the front-side interconnect structure 114 may also be performed.

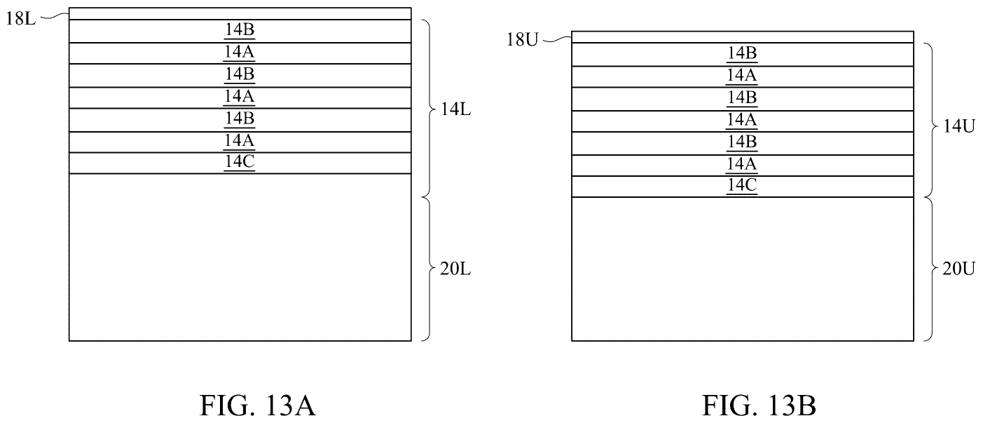

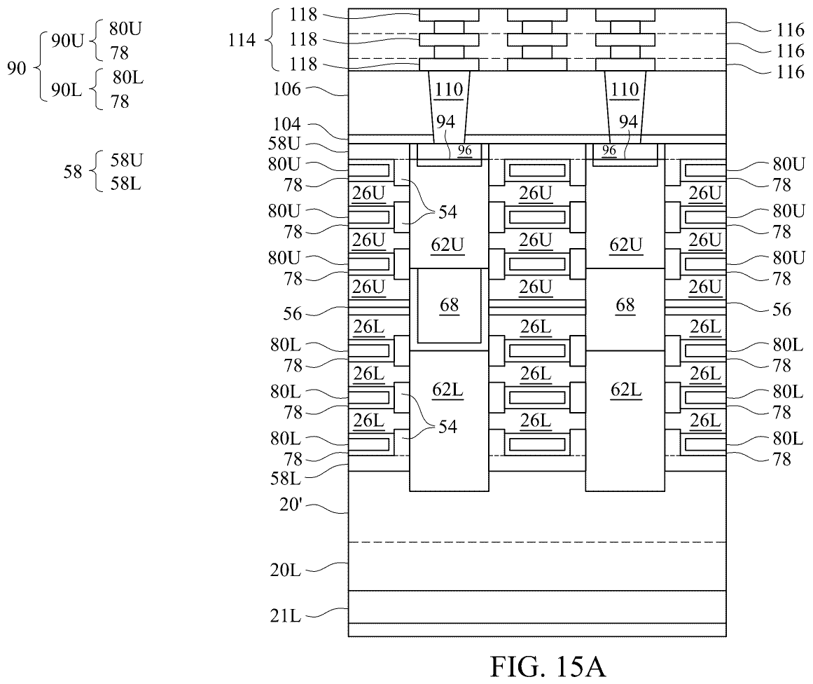

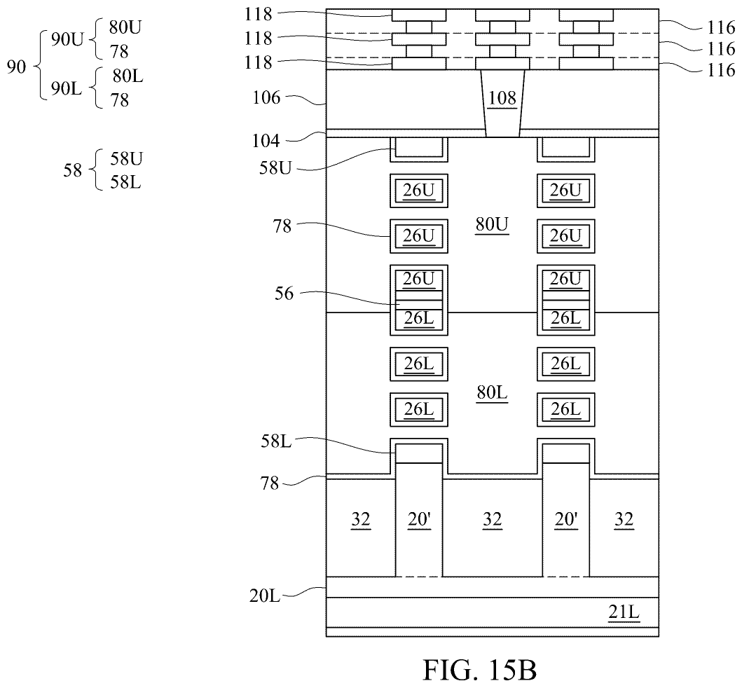

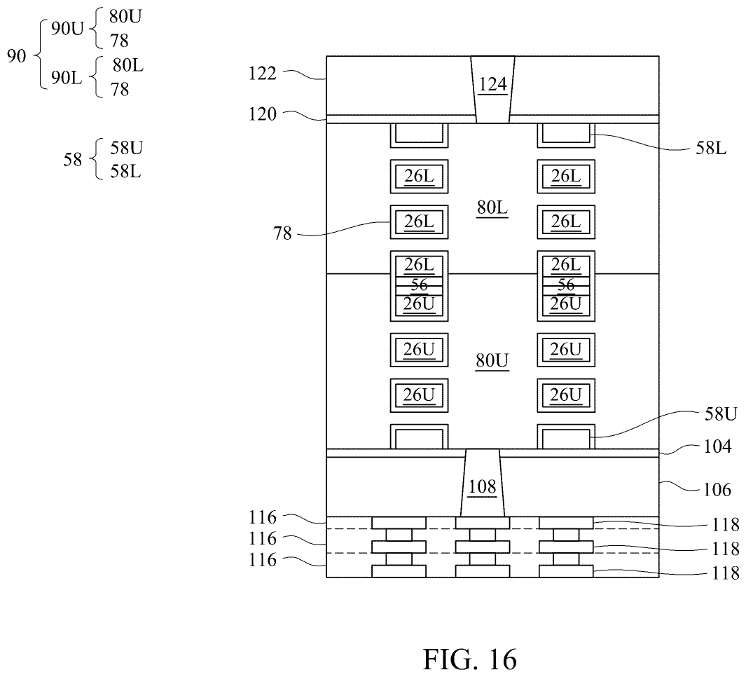

FIGS. 13A, 13B, 14, 15A, 15B, and 16 illustrate the cross-sectional views of intermediate stages in the formation of stacking transistors (as schematically represented in FIG. 1) in accordance with some embodiments. In FIGS. 13A, 13B, 14, 15A, 15B, and 16, the insulating protective structures 58 are separated from and not formed in direct contact with the semiconductor nanostructures 26. FIGS. 13A, 13B, 14, and 15A illustrates cross-sectional views along a similar cross-section as reference cross-section A-A′ in FIG. 1. FIGS. 15B and 16 illustrate cross-sectional views along a similar cross-section as reference cross-section B-B′ in FIG. 1.

FIGS. 13A and 13B illustrate cross-sectional views at a similar stage of manufacturing as FIGS. 2A and 2B, where like reference numerals indicate like elements formed by like processes as described above in FIGS. 2A and 2B unless otherwise indicated. As illustrated by FIGS. 13A and 13B, a different configuration of the layers of the multi-layer stacks 14U and 14L can be used to form another structure according to some embodiments. For example, a dummy semiconductor layer 14A can be inserted between the dummy semiconductor layer 14C and the adjacent semiconductor layer 14B (e.g., the lowermost semiconductor layer 14B) in each of the multi-layer stacks 14U and 14L.

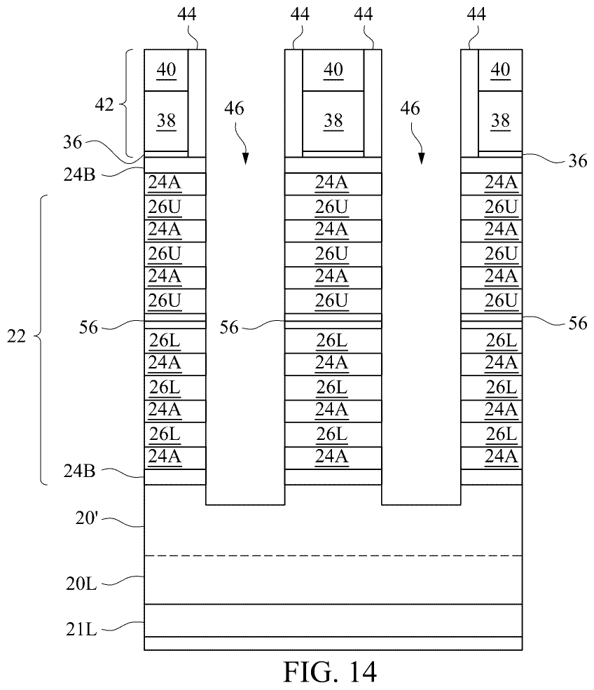

Additional processing steps, similar to those described above in FIGS. 3 through 6, may be applied to the structures of FIGS. 13A and 13B to arrive at the structure of FIG. 14. Specifically, the multi-layer stacks 14U and 14L may be bonded together and patterned to form various semiconductor nanostructures 26, dummy nanostructures 24A/24B, and dielectric isolation structures 56 in multi-layer stacks 22. Dummy gate stacks 42 may be formed over and along sidewalls of the multi-layer stacks 22, and source/drain recesses 46 may be patterned through the multi-layer stack 22. Due to the configuration of the multi-layer stacks 14U and 14L in FIGS. 13A and 13B, the structure of FIG. 14 may include dummy nanostructures 24B as the topmost and/or the bottommost layer of the multi-layer stacks 22.

FIGS. 15A and 15B illustrate cross-sectional views at a similar stage of manufacturing as FIGS. 10A and 10B, where like reference numerals indicate like elements formed by applying like processes as described above in FIGS. 7 through 10B to the structure of FIG. 14. Specifically, the dummy nanostructures 24B may be replaced with insulating protective layers 58; epitaxial source/drain regions 62U and 62L are formed in the source/drain recesses 46; and gate structures 90 may replace the dummy gate structures 42 and the dummy nanostructures 24A. As illustrated by FIGS. 15A and 15B, the insulating protective structures 58 may be physically separated from an immediately adjacent semiconductor nanostructure 26 by a gate structure 90. For example, the upper gate structure 90U may be disposed between the top insulating protective layer 58U and an adjacent, upper semiconductor nanostructure 26U, and the lower gate structure 90L may be disposed between the bottom insulating protective structure 58L and an adjacent, lower semiconductor nanostructure 26L. The upper insulating protective layer 58U may act as an etch stop layer/CMP stop layer for forming the upper gate structure 90U with a reduced height. As a result, device capacitance can be reduced and device performance is improved without increasing manufacturing defects. Similar to the embodiments of FIGS. 2A through 12, lateral surfaces of the upper insulating protective layer 58U, the gate dielectric 78, and the upper gate electrode 80U may be substantially level (within process variations).

Further, the insulating protective structures 58 may be connected to and physically contact adjacent ones of the inner spacers 54. Depending on whether the inner spacers 54 are formed in a same process or different processes as the insulating protective structures 58, a physical interface (represented by the dotted lines) may or may not be present between the insulating protective structures 58 and the adjoining inner spacers 54.

Additional process steps as may then be performed to remove the substrate 20L and form backside gate contacts 124 to the lower gate structures 90L. The resulting structure is illustrated in FIG. 16. The structure of FIG. 16 may be formed by applying the steps described above in FIGS. 11 and 12 to the structure of FIGS. 15A and 15B where like reference numerals indicate like elements formed by like processes. The lower insulating protective structures 58L may act as an etch stop layer/CMP stop layer while exposing the lower gate electrode 80L. As a result, backside gate contacts 124 can be formed with reduced manufacturing defects (e.g., over etching). Similar to the embodiments of FIGS. 2A through 12, lateral surfaces of the lower insulating protective structures 58L and the lower gate electrode 80L may be substantially level (within process variations).

In various embodiments, insulating protective layers are formed over and under vertically stacked channel regions of a stacking transistor. For example, an upper protection layer may be formed on a top surface of a topmost nanostructure of the vertically stacked channel regions, and/or a lower protection layer may be formed on a bottom surface of a bottommost nanostructure of the vertically stacked channel regions. The lower protection layer may provide an etch stop layer that facilitates the formation of a backside gate contact with fewer manufacturing errors. The upper protection layer may provide an etch stop layer for planarizing an upper gate stack of the upper transistor. In this manner, a gate height of the upper gate stack can be reduced, reducing device capacitance and improving performance.

In some embodiments, a semiconductor device includes a plurality of first nanostructures extending between first source/drain regions; a plurality of second nanostructures overlapping the plurality of first nanostructures, the plurality of second nanostructure extending between second source/drain regions; a first insulating protective layer overlapping the second nanostructures; a first gate stack around the plurality of first nanostructures; and a second gate stack over the first gate stack and disposed around the plurality of second nanostructures, wherein a lateral surface of the first insulating protective layer is level with a top surface of the second gate stack. Optionally, in some embodiments, the semiconductor device further includes a second insulating protective layer, wherein the plurality of first nanostructures overlap the second insulating protective layer, and wherein a bottom surface of the first gate stack is level with a lateral surface of the second insulating protective layer. Optionally, in some embodiments, the second insulating protective layer contacts a bottom first nanostructure of the plurality of first nanostructures. Optionally, in some embodiments, the first gate stack is disposed between a bottom first nanostructure of the plurality of first nanostructures and the second insulating protective layer. Optionally, in some embodiments, the first insulating protective layer contacts a top second nanostructure of the plurality of second nanostructures. Optionally, in some embodiments, the second gate stack is disposed between a top second nanostructure of the plurality of second nanostructures and the first insulating protective layer. Optionally, in some embodiments, the semiconductor device further includes first inner spacers between the first gate stack and the first source/drain regions; and second inner spacers between the second gate stack and the second source/drain regions, wherein the first inner spacers, the second inner spacers, and the first insulating protective layer have a same material composition. Optionally, in some embodiments, the semiconductor device further includes a dielectric isolation structure between the plurality of first nanostructures and the plurality of second nanostructures, wherein an interior of the dielectric isolation structure comprises a physical interface.

In some embodiments, a method of forming a semiconductor device includes forming a first multi-layer stack, the first multi-layer stack comprising: first semiconductor nanostructures that are alternating stacked with first dummy nanostructures; second semiconductor nanostructures that are alternating stacked with second dummy nanostructures, the second semiconductor nanostructures and the second dummy nanostructures each overlapping the first semiconductor nanostructures and the first dummy nanostructures; and a third dummy nanostructure overlapping the second semiconductor nanostructures and the second dummy nanostructures. The method further includes patterning a recess through the first multi-layer stack; replacing the third dummy nanostructure with first insulating protective structure; forming a first source/drain region in the recess adjacent the first semiconductor nanostructures; forming a second source/drain region over the first source/drain region in the recess, the second source/drain region being adjacent the second semiconductor nanostructures; and replacing the first dummy nanostructures with a first gate structure and the second dummy nanostructures with a second gate structure. Optionally, in some embodiments, replacing the second dummy nanostructures with the second gate structure comprises planarizing the second gate structure to expose the first insulating protective structure. Optionally, in some embodiments, the first multi-layer stack further comprises a fourth dummy nanostructure, wherein the first semiconductor nanostructures and the second dummy nanostructures each overlapping the fourth dummy nanostructure, and wherein the method further comprises replacing the fourth dummy nanostructure with a second insulating protective structure. Optionally, in some embodiments, the method further includes performing a planarization process to expose a backside of the first gate structure and the second insulating protective structure. Optionally, in some embodiments, the first multi-layer stack further comprises an isolation structure between the first semiconductor nanostructures and the second semiconductor nanostructures. Optionally, in some embodiments, forming the first multi-layer stack comprises: bonding a second multi-layer stack to a third multi-layer stack, the second multi-layer stack comprising first semiconductor layers and first dummy semiconductor layers, the second multi-layer stack comprising second semiconductor layers and second dummy semiconductor layers that are alternatingly stacked over a third dummy semiconductor layer; and after bonding the second multi-layer stack to the third multi-layer stack, patterning the second multi-layer stack and the third multi-layer stack to form the first multi-layer stack. Optionally, in some embodiments, bonding the second multi-layer stack to the third multi-layer stack comprises dielectric-to-dielectric bonding.

In some embodiments, a method includes forming a multi-layer stack comprising: first semiconductor nanostructures that are alternatingly stacked with first dummy nanostructures; and a second dummy nanostructure over the first semiconductor nanostructures and the first dummy nanostructures. The method further includes replacing the second dummy nanostructure with a first insulating protective layer; removing the first dummy nanostructures; forming a first gate structure around lower ones of the first semiconductor nanostructures; and forming a second gate structure around upper ones of the first semiconductor nanostructures. Forming the second gate structure comprises performing a first planarization process to remove upper portions of the second gate structure, and wherein the first insulating protective layer masks the first semiconductor nanostructures during the first planarization process. Optionally, in some embodiments, the multi-layer stack further comprises a third dummy nanostructure under the first semiconductor nanostructures and the first dummy nanostructures, wherein the method further comprises: replacing the third dummy nanostructure with a second insulating protective layer. Optionally, in some embodiments, the method further includes performing a second planarization process on a backside of the first gate structure, wherein the second insulating protective layer masks the first semiconductor nanostructures during second planarization process. Optionally, in some embodiments, the second dummy nanostructure is in direct contact with a top semiconductor nanostructure of the first semiconductor nanostructures. Optionally, in some embodiments, forming the second gate structure comprises forming the second gate structure between the first insulating protective layer and a top semiconductor nanostructure of the first semiconductor nanostructures.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor device comprising:
a plurality of first nanostructures extending between first source/drain regions;
a plurality of second nanostructures overlapping the plurality of first nanostructures, the plurality of second nanostructure extending between second source/drain regions;
a first insulating protective layer overlapping the second nanostructures;
a first gate stack around the plurality of first nanostructures; and
a second gate stack over the first gate stack and disposed around the plurality of second nanostructures, wherein a lateral surface of the first insulating protective layer is level with a top surface of the second gate stack.

2. The semiconductor device of claim 1, further comprising:
a second insulating protective layer, wherein the plurality of first nanostructures overlap the second insulating protective layer, and wherein a bottom surface of the first gate stack is level with a lateral surface of the second insulating protective layer.

3. The semiconductor device of claim 2, wherein the second insulating protective layer contacts a bottom first nanostructure of the plurality of first nanostructures.

4. The semiconductor device of claim 2, wherein the first gate stack is disposed between a bottom first nanostructure of the plurality of first nanostructures and the second insulating protective layer.

5. The semiconductor device of claim 1, wherein the first insulating protective layer contacts a top second nanostructure of the plurality of second nanostructures.

6. The semiconductor device of claim 1, wherein the second gate stack is disposed between a top second nanostructure of the plurality of second nanostructures and the first insulating protective layer.

7. The semiconductor device of claim 1 further comprising:
first inner spacers between the first gate stack and the first source/drain regions; and
second inner spacers between the second gate stack and the second source/drain regions, wherein the first inner spacers, the second inner spacers, and the first insulating protective layer have a same material composition.

8. The semiconductor device of claim 1 further comprising a dielectric isolation structure between the plurality of first nanostructures and the plurality of second nanostructures, wherein an interior of the dielectric isolation structure comprises a physical interface.

9. A method of forming a semiconductor device, the method comprising:
forming a first multi-layer stack, the first multi-layer stack comprising:
first semiconductor nanostructures that are alternating stacked with first dummy nanostructures;
second semiconductor nanostructures that are alternating stacked with second dummy nanostructures, the second semiconductor nanostructures and the second dummy nanostructures each overlapping the first semiconductor nanostructures and the first dummy nanostructures; and
a third dummy nanostructure overlapping the second semiconductor nanostructures and the second dummy nanostructures;
patterning a recess through the first multi-layer stack;
replacing the third dummy nanostructure with first insulating protective structure;
forming a first source/drain region in the recess adjacent the first semiconductor nanostructures;
forming a second source/drain region over the first source/drain region in the recess, the second source/drain region being adjacent the second semiconductor nanostructures; and
replacing the first dummy nanostructures with a first gate structure and the second dummy nanostructures with a second gate structure.

10. The method of claim 9, wherein replacing the second dummy nanostructures with the second gate structure comprises planarizing the second gate structure to expose the first insulating protective structure.

11. The method of claim 9, wherein the first multi-layer stack further comprises a fourth dummy nanostructure, wherein the first semiconductor nanostructures and the second dummy nanostructures each overlapping the fourth dummy nanostructure, and wherein the method further comprises replacing the fourth dummy nanostructure with a second insulating protective structure.

12. The method of claim 11 further comprising performing a planarization process to expose a backside of the first gate structure and the second insulating protective structure.

13. The method of claim 9, wherein the first multi-layer stack further comprises an isolation structure between the first semiconductor nanostructures and the second semiconductor nanostructures.

14. The method of claim 9, wherein forming the first multi-layer stack comprises:
bonding a second multi-layer stack to a third multi-layer stack, the second multi-layer stack comprising first semiconductor layers and first dummy semiconductor layers, the second multi-layer stack comprising second semiconductor layers and second dummy semiconductor layers that are alternatingly stacked over a third dummy semiconductor layer; and
after bonding the second multi-layer stack to the third multi-layer stack, patterning the second multi-layer stack and the third multi-layer stack to form the first multi-layer stack.

15. The method of claim 14, wherein bonding the second multi-layer stack to the third multi-layer stack comprises dielectric-to-dielectric bonding.

16. A method comprising:
forming a multi-layer stack comprising:
first semiconductor nanostructures that are alternatingly stacked with first dummy nanostructures; and
a second dummy nanostructure over the first semiconductor nanostructures and the first dummy nanostructures;
replacing the second dummy nanostructure with a first insulating protective layer;
removing the first dummy nanostructures;
forming a first gate structure around lower ones of the first semiconductor nanostructures; and
forming a second gate structure around upper ones of the first semiconductor nanostructures, wherein forming the second gate structure comprises performing a first planarization process to remove upper portions of the second gate structure, and wherein the first insulating protective layer masks the first semiconductor nanostructures during the first planarization process.

17. The method of claim 16, wherein the multi-layer stack further comprises a third dummy nanostructure under the first semiconductor nanostructures and the first dummy nanostructures, wherein the method further comprises:
replacing the third dummy nanostructure with a second insulating protective layer.

18. The method of claim 17, further comprising:
performing a second planarization process on a backside of the first gate structure, wherein the second insulating protective layer masks the first semiconductor nanostructures during second planarization process.

19. The method of claim 16, wherein the second dummy nanostructure is in direct contact with a top semiconductor nanostructure of the first semiconductor nanostructures.

20. The method of claim 16, wherein forming the second gate structure comprises forming the second gate structure between the first insulating protective layer and a top semiconductor nanostructure of the first semiconductor nanostructures.
